(19) United States
(12) Patent Application Publication
(10) Pub. No.: US 2007/0063300 A1
(43) Pub. Date: Mar. 22, 2007

(54) CMOS image sensor and method for fabricating the same

(76) Inventor: Joon Hwang, Cheongju-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/525,663

(22) Filed: Sep. 22, 2006

(30) Foreign Application Priority Data
Sep. 22, 2005 (KR) 10-2005-0088088

(51) Int. Cl. H01L 31/0232

(52) U.S. Cl. 257/432; 257/E33.068; 257/E31.121

(57) ABSTRACT

A CMOS image sensor and a method for fabricating the same are provided. The CMOS Image sensor includes a semiconductor substrate having a photodiode and transistors. An interlayer insulating layer is formed on the entire surface of the semiconductor substrate. First, second, and third color filter layers are formed at regular intervals on the interlayer insulator. First, second, and third microlenses are formed on the first, second, and third color filter layers, respectively. The microlenses have at least two different curvatures.

### RELATED APPLICATION

This application claims the benefit under 35 U.S.C. §119(e), of Korean Patent Application Number 10-2005-0088088 filed Sep. 22, 2005, which is incorporated herein by reference in its entirety.

### FIELD OF THE INVENTION

The present invention relates to an image sensor and a method for fabricating the same, and more particularly, to a CMOS image sensor providing an improved light-receiving efficiency and a method for fabricating the same.

### BACKGROUND OF THE INVENTION

Generally, an image sensor is a semiconductor device for converting an optical image into an electrical signal, and is broadly classified as a CCD (Charge Coupled Device) image sensor or a CMOS (Complementary Metal Oxide Semiconductor) image sensor.

The CMOS image sensor includes a photodiode for sensing an irradiated light, and a CMOS logic circuit for converting the sensed light into an electrical signal, wherein the photosensitivity of the image sensor increases as the light-receiving capacity of the photodiode increases.

FIG. 1 is a schematic view showing a CMOS image sensor according to the related art, and FIG. 2 is a plan view showing the arrangement of a plurality of pixel arrays in the related art CMOS image sensor.

As shown in FIG. 1, the related art CMOS image sensor includes an image sensor array 10, a plurality of microlenses 20 formed on the image sensor array 10, and a condenser lens 30 for condensing light onto the microlens 20.

Various image sensors generally condense and guide lights as shown in FIG. 1. At this point, the incidence angle of light increases away from a pixel array center (A) in the directions of axes X and Y, as illustrated in FIGS. 1 and 2. The maximum incidence angle is about 20° to 30°.

Hereinafter, the related art CMOS image sensor will be described in detail with reference to the accompanying drawings.

FIG. 3 is a sectional view taken along line IV-IV′ of FIG. 2 to show the related art CMOS image sensor.

As shown in FIG. 3, the related art CMOS image sensor includes a semiconductor substrate 11, one or more photodiodes 12 formed on the semiconductor substrate 11 to generate electric charge corresponding to the intensity of incident light, an interlayer insulating layer 13 formed on the entire surface of the semiconductor substrate 11 including the photodiodes 12, an R/G/B color filter layer 14 formed on the interlayer insulator 13 to transmit light beams with predetermined wavelengths, a planarization layer 15 formed on the entire surface of the semiconductor substrate 11 including the color filter layer 14, and a plurality of microlenses 16 formed on the planarization layer 15. The microlenses 16 have a convex shape with a constant curvature. The microlenses 16 receive light from the color filter layer 14 and concentrate the received light onto the photodiode 12.

Although not shown in FIG. 3, an optical shielding layer may be formed in the interlayer insulating layer 13 to prevent light from being incident upon regions other than a photodiode region.

The photodiodes may be replaced by photogates.

The color filter layer 14 includes R (red), G (green) and B (blue) color filters. Each of the color filters is formed by depositing a corresponding photosensitive material and performing a photolithography process using a separate mask on the resulting structure.

Also, the curvature and the height of the microlens 16 are determined considering various factors such as the focus of condensed light. A photoresist is generally used and the microlens 16 is formed through deposition, patterning and reflow.

In case of left tilted incident light, the microlens 16 of the CMOS image sensor cannot guide light \textcircled{1} to the corresponding photodiode 12 of its pixel, but can guide light \textcircled{2} to the corresponding photodiode 12 of its pixel.

In case of right tilted incident light, the microlens 16 can guide light \textcircled{3} into the corresponding photodiode 12 of its pixel but cannot guide light \textcircled{4} into the corresponding photodiode 12 of its pixel.

However, the related art CMOS image sensor has the following problems.

Because the microlenses 16 have a constant curvature and are formed uniformly in the entire pixel array, they cannot guide incident light titled to the left or the right to a photodiode, as indicated by \textcircled{1}, \textcircled{2}, \textcircled{3}, and \textcircled{4} of FIG. 3.

The related art CMOS image sensor cannot produce images with good quality because lens shading occurs due to variable sensitivity that increases to the center of a wafer and decreases towards the array edge.

### SUMMARY OF THE INVENTION

Accordingly, the present invention is directed to a CMOS image sensor and method for fabricating the same that addresses and/or substantially obviates one or more problems, limitations, and/or disadvantages of the related art.

An object of the present invention is to provide a CMOS image sensor for improving an image quality by forming a microlens to have an optimal shape according to the difference of incidence angles of locations in a sensor array so as to provide uniform sensitivity, and a method for fabricating the same.

Additional advantages, objects, and features of the invention will be set forth in part in the description which follows and in part will become apparent to those having ordinary skill in the art upon examination of the following or may be learned from practice of the present invention. The objectives and other advantages of the invention may be realized and attained by the structure particularly pointed out in the written description and claims hereof as well as the appending drawings.

To achieve these objects and other advantages and in accordance with the purpose of the invention, as embodied and broadly described herein, there is provided a CMOS image sensor, including: a semiconductor substrate having a photodiode and transistors; an interlayer insulating layer formed on the entire surface of the semiconductor substrate; first, second, and third color filter layers formed at regular intervals on the interlayer insulator; and first, second, and third microlenses formed on the first, second, and third color filter layers, respectively, wherein the first, second, and third microlenses have at least two different curvatures.

In another aspect of the present invention, there is provided a method for fabricating a CMOS image sensor, including: forming an interlayer insulating layer on an entire surface of a semiconductor substrate having a photodiode and transistors; forming a plurality of color filter layers at regular intervals on the interlayer insulating layer; and forming a plurality of microlenses corresponding to each of the color filter layers, where the plurality of microlenses have at least two different curvatures.

In a further another aspect of the present invention, there is provided a method for fabricating a CMOS image sensor, including: forming an interlayer insulating layer on an entire surface of a semiconductor substrate having a photodiode and various transistors; forming first, second, and third color filter layers at regular intervals on the interlayer insulating layer; forming first, second, and third microlens patterns having different step differences corresponding to the first, second, and third color filter layers; and forming first, second, and third microlenses having different curvatures by reflowing the first, second, and third microlens patterns.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment (s) of the invention and together with the description serve to explain the principle of the invention. In the drawings:

FIG. 1 is a schematic view of a CMOS image sensor according to the related art;

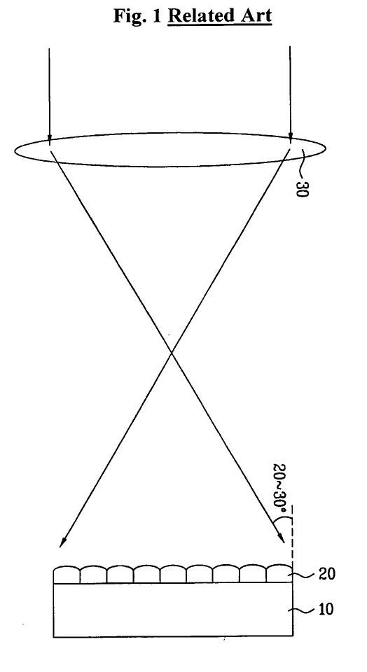

FIG. 2 is a plan view showing the arrangement of a plurality of pixel arrays in the related art CMOS image sensor;

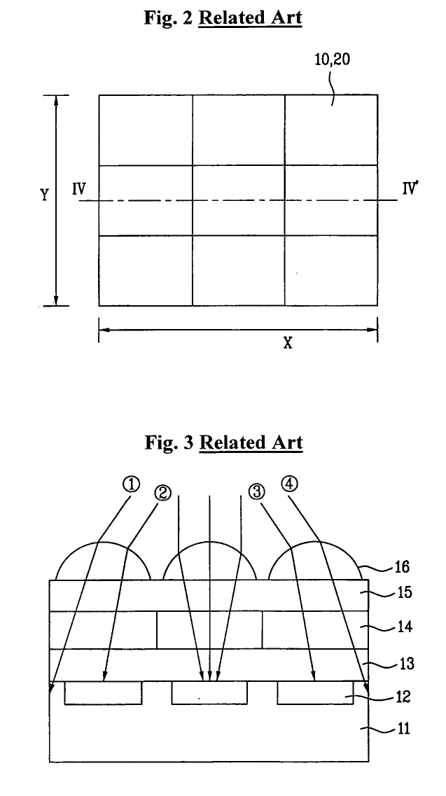

FIG. 3 is a sectional view taken along line IV-IV′ of FIG. 2 to show the related art CMOS image sensor;

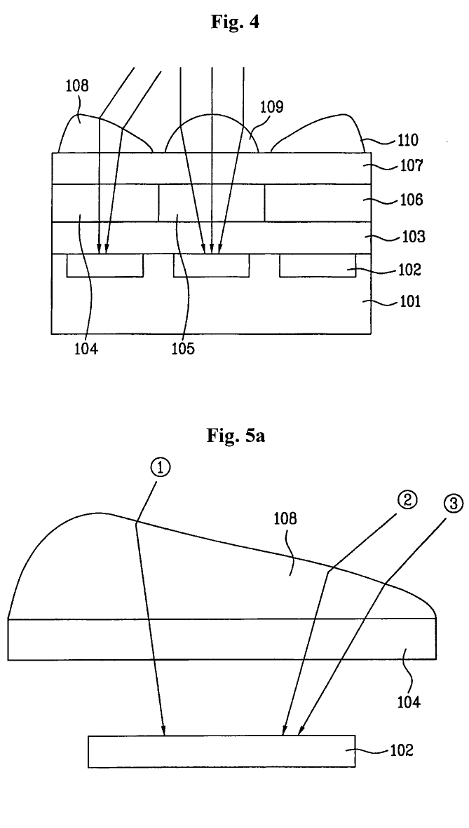

FIG. 4 is a sectional view taken along line IV-IV′ of FIG. 2 to show a CMOS image sensor according to an embodiment of the present invention;

FIGS. 5A to 5C are diagrams showing the path of incident light traveling to a photodiode through each of microlenses in the CMOS image sensor shown in FIG. 4; and

FIGS. 6A to 6D are sectional views illustrating a method for fabricating a CMOS image sensor according to an embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a CMOS image sensor according to the present invention and a method for fabricating the CMOS image sensor will be described in detail with reference the accompanying drawings.

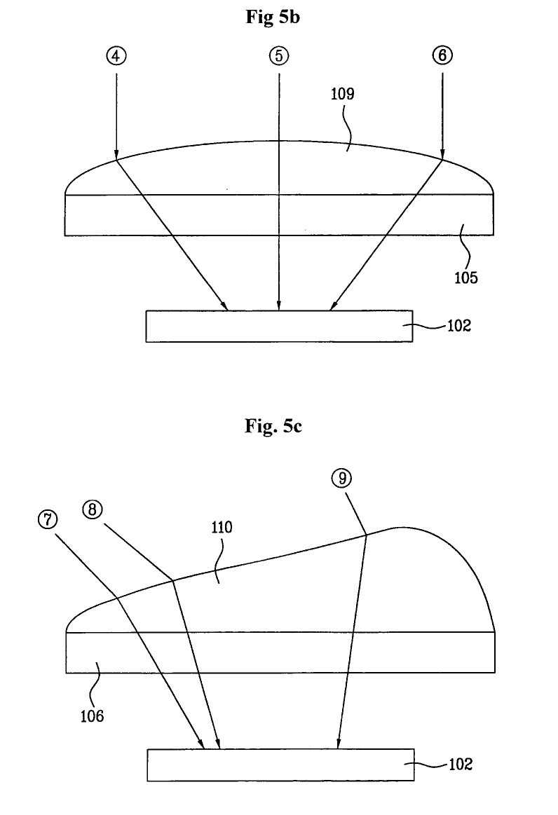

FIG. 4 is a sectional view of a CMOS image sensor according to an embodiment of the present invention.

Referring to FIG. 4, the CMOS image sensor can include a semiconductor substrate 101 having a photodiode 102 and transistors formed thereon to constitute a unit pixel of the CMOS image sensor; an interlayer insulating layer 103 formed on the entire surface of the semiconductor substrate 101; first, second, and third color filter layers 104, 105, and 106 formed at regular intervals on the interlayer insulating layer 103; a planarization layer 107 formed on the entire surface of the semiconductor substrate 101 including the first, second, and third color filter layers 104, 105, and 106; a first microlens 108 formed on the planarization layer 107 in such a way that it corresponds to the first color filter 104 and has a non-uniform curvature which is more protruded at an outer portion than at an inner portion; a second microlens 109 formed on the planarization layer 107 in such a way that it corresponds to the second color filter layer 104 and has a uniform curvature; and a third microlens 110 formed on the planarization layer 107 in such a way that it corresponds to the third color filter layer 106 and has a non-uniform curvature which is more protruded at an outer portion than at an inner portion.

As described above, the CMOS image sensor composed of a plurality of pixel arrays includes three micro-lenses with different curvature. That is, the microlens formed at a central region has a curvature different from those of the micro-lenses formed at the left and right sides. That is, the micro-lenses at the left and right sides have a convex shape, where an outer portion thereof is more protruded than at an inner portion, which is reflected in the outer portion having a larger curvature than the inner portion.

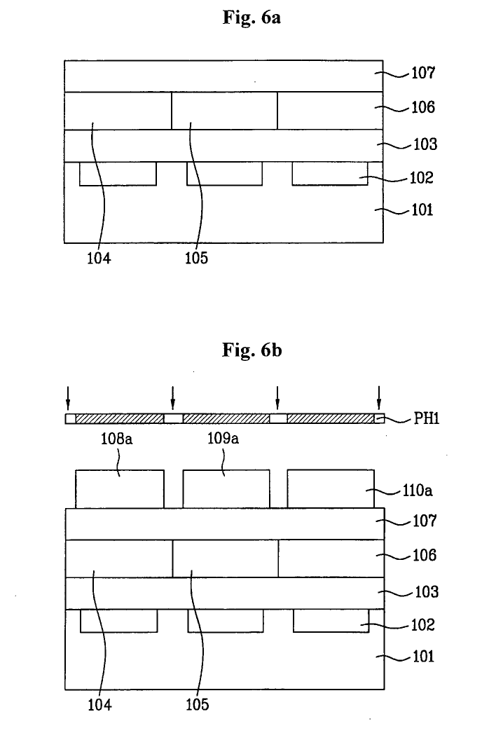

FIGS. 5A to 5C are diagrams showing the path of incident light traveling to a photodiode through each of microlenses in the CMOS image sensor shown in FIG. 4.

As shown in FIG. 5A, the first microlens 108 can have a variable curvature in which an outer portion thereof is more protruded than at an inner portion thereof such that incident lights \textcircled{1}, \textcircled{2}, and \textcircled{3}, which are tilted to the left, can be bent in the protruded region and irradiated onto the corresponding photodiode 102 through the first microlens 108.

As shown in FIG. 5B, the second microlens 109 in the central region is formed to have a constant curvature as described in the prior art such that incident light beams \textcircled{4}, \textcircled{5} and \textcircled{6} can be irradiated onto the corresponding photodiode 102.

As shown in FIG. 5C, the third microlens 110 can have a variable curvature in which an outer portion thereof is more protruded than at an inner portion thereof such that incident lights \textcircled{7}, \textcircled{8} and \textcircled{9}, which are tilted to the right, can be bent at the protruded region and irradiated onto the corresponding photodiode 102 through the third microlens 110.

As shown in FIGS. 5A to 5C, the outer portions of the first microlens 108 and the third microlens 110 are protruded higher than the inner portion thereof, which are formed at the left side and at the right side of the second microlens, respectively.

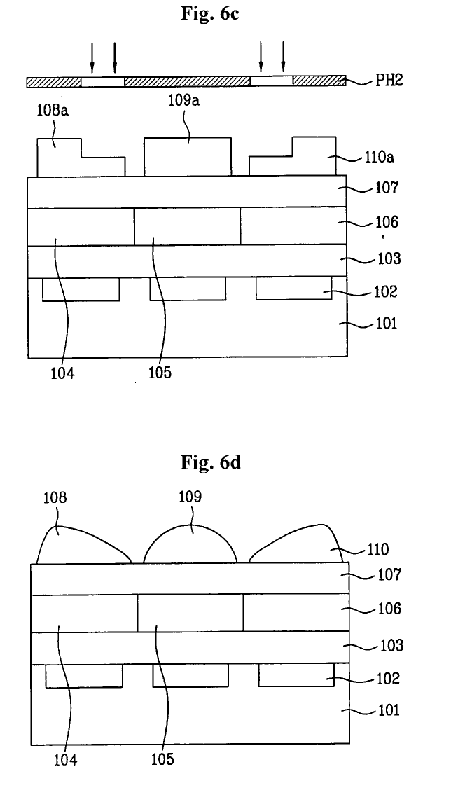

FIG. 6A to 6D are sectional views illustrating a method for fabricating a CMOS image sensor according to an embodiment of the present invention.

As shown in FIG. 6A, a photodiode 102 and transistors (not shown), which constitute a unit pixel, can be formed on the semiconductor substrate 101.

Thereafter, the interlayer insulating layer 103 can be formed on the entire surface of the semiconductor substrate 101 including the photodiode 102.

In one embodiment, the interlayer insulating layer 103 may be formed in a multi-layer structure (not shown). In a specific embodiment, after forming one interlayer insulating layer, an optical shielding layer can be formed on the interlayer insulating layer to prevent the light from being incident upon the photodiode 102, and another interlayer insulating layer may formed thereon.

In an embodiment, the interlayer insulating layer 103 may be formed using an oxide such as undoped silicate glass (USG).

Thereafter, first, second and third color filter layers 104, 105, and 106 can be formed on the interlayer insulating layer 103 by depositing photosensitive material on the interlayer insulating layer 103 and selectively patterning the photosensitive material by photolithography and exposing processes.

The color filter layers 104, 105, and 106 for filtering light with predetermined wavelength can be formed by depositing a dyeable resist and performing exposing and developing processes.

In a specific embodiment, each of the color filter layers 104, 105, and 106 can be coated with the corresponding photosensitive material to a thickness of 1 to 5 μm. Then, the color filter layers can be patterned by photolithography using a separate mask, thereby forming a single color filter layer that filters the light with a predetermined wavelength.

The planarization layer 107 can be formed on the entire surface of the semiconductor substrate 101 including the color filter layers 104, 105, and 106.

As shown in FIG. 6B, a microlens material layer can be formed on the planarization layer 107 and a first photo mask PM1 can be arranged above the microlens material layer.

Then, first, second, and third microlens patterns 108a, 109a, and 110a can be formed at regular intervals by exposing the microlens material layer to a first UV radiation using the first photo mask and developing the exposed regions.

Here, the first, second, and third microlens patterns 108a, 109a, and 110a can be formed corresponding to the first, second, and third color filter layers 104, 105, and 106, respectively.

As shown in FIG. 6C, a second photo mask PM2 can be disposed above the semiconductor substrate 101, and the inside portion of the first microlens pattern 108a and the third microlens pattern 110a can be exposed to a second UV radiation with less energy than the first UV radiation using the second photo mask PM2.

Thereafter, height differences can be formed at the inside and the outside of the first microlens pattern 108a and the third microlens pattern 110a by developing the second exposed regions.

Herein, the step portion between the inside portion and the outer portion of the first microlens pattern 108a and the third microlens pattern 110a causes an outer portion to be thicker than an inner portion of the first microlens pattern 108a and the third microlens pattern 110a.

That is, the first microlens pattern 108a and the third microlens pattern 110a can be formed at the left side and the right side of the second microlens pattern 109a, respectively, and the outer portion and the inner portion of the first and third microlens patterns 108a and 110a can have different thicknesses due to the height difference.

As shown in FIG. 6D, the first, second, and third microlens patterns 108a, 109a, and 110a can be reflowed to form a first, second, and third microlens 108, 109, and 110 corresponding to the first, second, and third color filter layers 104, 105, and 106, respectively.

In embodiment, the microlens material layer may be made of an insulating layer such as an oxide layer or a photoresist.

Also, a hot plate or a furnace can be used in the reflow process. At this time, the curvature of the microlenses can vary depending on a shrinking/heating process, and therefore a condensing efficiency varies depending on the curvature.

Then, the first, second, and third microlenses 108, 109, and 110 can be hardened by radiating UV rays.

In a specific embodiment, the optimal curvatures of the first, second, and third microlenses 108, 109, and 110 can be sustained by hardening the first, second, and third microlenses 108, 109, and 110 through radiating UV rays. In one embodiment, the hardening can be performed using a laser.

The planarization layer 107 is formed in the embodiments of the present invention described above. However, the first, second, and third microlenses 108, 109, and 110 may be formed directly on the first, second, and third color filter layers 104, 105, and 106 without forming the planarization layer 107.

As described above, the CMOS image sensor according to the present invention and the method for fabricating the same have following advantages.

The CMOS image sensor according to the present invention can improve an image quality by forming a microlens to have an optimal shape according to the difference of incidence angles of locations in a sensor array so as to provide uniform sensitivity.

It will be apparent to those skilled in the art that various modifications and variations can be made in the present invention. Thus, it is intended that the present invention covers the modifications and variations of this invention provided they come within the scope of the appended claims and their equivalents.

I claim:

1. A CMOS image sensor, comprising:
a semiconductor substrate having a photodiode and transistors;
an interlayer insulating layer formed on the entire surface of the semiconductor substrate;
first, second, and third color filter layers formed at regular intervals on the interlayer insulating layer; and
a first microlens corresponding to the first color filter layer, a second microlens corresponding to the second color filter layer, and a third microlens corresponding to the third color filter layer formed on each corresponding color filter layer, wherein the first, second, and third microlenses have at least two different curvatures.

2. The CMOS image sensor according to claim 1, wherein the second microlens corresponding to the second color filter layer in a central region of the semiconductor substrate has a generally-uniform curvature.

3. The CMOS image sensor according to claim 2, wherein the first and third microlenses are arranged at left and right sides, respectively, of the second microlens disposed at the central region, and the curvature of the portions of the first microlens and the third microlens adjacent to the second microlens is different from the curvature of the opposite portions thereof.

4. The CMOS image sensor according to claim 2, wherein the first and third microlenses are arranged at left and right sides, respectively, of the second microlens disposed at the central region, and the curvature of the portions of the first microlens and the third microlens adjacent to the second microlens is less than the curvature of the opposite portions thereof.

5. The CMOS image sensor according to claim 1, wherein a surface of the first, second, and third microlenses has a round shape.

6. The CMOS image sensor according to claim 1, further comprising a planarization layer formed on the entire surface of the semiconductor substrate including the first, second, and third color filter layers.

7. A method for fabricating a CMOS image sensor, comprising:
forming an interlayer insulating layer on an entire surface of a semiconductor substrate having a photodiode and transistors;
forming a plurality of color filter layers at regular intervals on the interlayer insulating layer; and
forming a plurality of microlenses corresponding to each of the color filter layers, wherein the plurality of microlenses have at least two different curvatures.

8. The method according to claim 7, wherein a centrally located microlens of the plurality of microlenses corresponding to a centrally located color filter layer of the plurality of color filter layers has a uniform curvature.

9. The method according to claim 8, wherein for microlenses arranged at left and right sides of the centrally located microlens, the curvature of portions of the microlenses adjacent to the centrally located microlens is different from the curvature of opposite portions thereof.

10. The method according to claim 8, wherein for microlenses arranged at left and right sides of the centrally located microlens, the curvature of portions of the microlesnses adjacent to the central microlens is less than the curvature of opposite portions thereof.

11. The method according to claim 7, wherein a surface of each of the plurality of microlenses has a round shape.

12. The method according to claim 7, further comprising forming a planarization layer on the entire surface of the semiconductor substrate including the plurality of color filter layers.

13. A method for fabricating a CMOS image sensor, comprising:
forming an interlayer insulating layer on an entire surface of a semiconductor substrate having a photodiode and transistors;
forming first, second, and third color filter layers at regular intervals on the interlayer insulating layer;
forming a first microlens pattern corresponding to the first color filter layer, a second microlens pattern corresponding to the second color filter layer, and a third microlens pattern corresponding to the third color filter layer, wherein the first, second, and third microlens patterns each have different step differences; and
forming first, second, and third microlenses having different curvatures by reflowing the first, second, and third microlens patterns.

14. The method according to claim 13, wherein forming the first microlens pattern corresponding to the first color filter layer, the second microlens pattern corresponding to the second color filter layer, and the third microlens pattern corresponding to the third color filter layer, comprises:
depositing a resist layer for a microlens on the entire surface of the semiconductor substrate including the first, second, and third color filter layers;
performing a first exposure by by selectively exposing and developing the resist layer; and
forming a step difference for the first, second, and third microlens patterns by exposing and developing inner regions of the first microlens pattern and the third microlens pattern using a lower energy than the first exposure.

15. The method according to claim 13, wherein the second microlens pattern is formed to have a constant step difference.

16. The method according to claim 13, wherein the second microlens is formed to have a constant curvature.

17. The method according to claim 13, wherein the first microlens is formed at one side of the second microlens and the third microlens is formed at the other side of the second microlens.

18. The method according to claim 13, further comprising hardening the first, second, and third microlenses.

19. The method according to claim 13, wherein the first and third microlenses are arranged at left and right sides, respectively of the second microlens disposed at a central region of the substrate, and the curvature of portions of the first microlens and the third microlens adjacent to the second microlens is different from the curvature of the opposite portions thereof.

20. The method according to claim 13, wherein the first and third microlenses are arranged at left and right sides, respectively, of the second microlens disposed at a central region of the substrate, and the curvature of portions of the first microlens and the third microlens adjacent to the second microlens is less than the curvature of the opposite portions thereof.
